(19) United States
(12) Patent Application Publication
(10) Pub. No.: US 2024/0313509 A1
(43) Pub. Date: Sep. 19, 2024

(54) OPTOELECTRONIC COMPONENT THAT IS INSENSITIVE TO DISLOCATIONS

(71) Applicants: CENTRE NATIONAL DE LA RECHERCHE SCIENTIFIQUE, PARIS (FR); UNIVERSITE DE MONTPELLIER, MONTPELLIER (FR)

(72) Inventors: Jean Baptiste RODRIGUEZ, Saint-Gély du Fesc (FR); Alexei BARANOV, MONTPELLIER (FR); Laurent CERUTTI, Saint Jean de Vedas (FR); Eric TOURNIE, MONTPELLIER (FR)

(21) Appl. No.: 18/575,153

(22) PCT Filed: Jun. 30, 2022
(86) PCT No.: PCT/EP2022/068188

§ 371 Date: Dec. 28, 2023

(30) Foreign Application Priority Data
Jul. 1, 2021 (FR) FR2107138

(51) Int. Cl. H01S 5/343; H01S 5/02; H01S 5/34

(52) U.S. Cl. CPC H01S 5/34346; H01S 5/0218; H01S 5/3422

(57) ABSTRACT

The invention relates to an optoelectronic component (1) that is insensitive to dislocations, comprising:

a semiconductor heterostructure (2) able to emit laser radiation, said semiconductor heterostructure being formed from first semiconductors comprising a cascade of gain-providing active regions (21) in which the inter-band radiative transition is of type II, and

a carrier structure (30) comprising a non-native substrate (3) different from the first semiconductors, said semiconductor heterostructure (2) being formed by epitaxial growth on the carrier structure (30),

wherein the active regions have a dislocation density higher than 10⁷ .cm⁻².

### CROSS-REFERENCE TO RELATED APPLICATIONS

This application is the U.S. national phase of International Application No. PCT/EP2022/068188 filed Jun. 30, 2022 which designated the U.S. and claims priority to FR 2107138 filed Jul. 1, 2021, the entire contents of each of which are hereby incorporated by reference.

### TECHNICAL FIELD OF THE INVENTION

The present invention generally relates to light-emitting optoelectronic components based on semiconductors composed on non-native substrates.

The invention shows a particularly advantageous application for integration of light-emitting optoelectronic components in or on photonic integrated circuits.

### STATE OF THE ART

Integrating light-emitting optoelectronic components based on semiconductor materials, such as lasers or light-emitting diodes, on non-native substrates, i.e. a substrate formed of a material that is different from the materials forming the component, makes it possible to extend the field of application and to reduce the manufacturing costs thereof.

Indeed, certain technological sectors, for example those based on silicon or gallium arsenide substrates, have developed for many years and benefit from cost advantages. They thus open the prospect of being able to use mature integration technologies, such as the manufacturing processes of the microelectronic industry, to make photonic components. Moreover, photonic on silicon is a very promising area of research aiming at integrating photonic functions with electronic circuits on the silicon wafer scale.

Integration of semiconductor components on a non-native substrate can be made by mainly two methods: either in a so-called heterogeneous manner, i.e. by bonding semiconductor layers or components on the non-native substrate, or in a so-called monolithic manner, i.e. by epitaxial growth of semiconductor layers directly on the non-native substrate.

Epitaxial growth on a substrate that does not have the same mesh parameter as the epitaxed material causes the presence of dislocations within the component formed. Dislocations are linear (i.e. non-point) defects, corresponding to a discontinuity in the crystal structure arrangement. They have a particular influence on the electronic properties of the semiconductor materials.

It is noted and recognized that quantum-well lasers have dislocation sensitivity and that quantum-well lasers epitaxed on non-native substrates consequently experience a deterioration in their performance due to dislocations generated by the epitaxial growth. For example, mention can be made to articles “Realization of GaAs/AlGaAs lasers on Si substrates using epitaxial lateral overgrowth by metalorganic chemical vapor deposition” by Kazi et al., or “Theoretical Study on the Effects of Dislocations in Monolithic III-V Lasers on Silicon” by Hantschmann et al., that highlight this problem.

The article “Lasing Characteristics and Reliability of 1550 nm laser monolithically grown on Si” by Shi et al. mentions the operating constraints of indium-phosphide laser diodes made by epitaxial growth on a silicon substrate. A shorter lifetime of the laser and a threshold current increased by one order of magnitude with respect of the laser diodes epitaxed on a native substrate have in particular been observed. This performance decrease is allocated to leakages of charge carriers via the dislocations.

Quantum-box lasers, described for example in the articles “Photonic Integration With Epitaxial III-V on Silicon” by A. Liu et J. Bowers, or “Low-Threshold Epitaxially Grown 1.3-μm InAs Quantum Dot Lasers on Patterned (001) Si” by Shang et al., have been made by epitaxial growth on a non-native substrate. These latter have better performances compared with quantum-well lasers made according to the same method.

However, the performances of the quantum-box lasers made on a non-native substrate remains limited by the dislocation density. The latter must remain low, of the order of 10⁶-10⁷ cm⁻², to ensure the proper operation of these lasers, as described in the articles “Origin of defect tolerance in InAs/GaAs quantum dot lasers grown on Si”, by Liu et al., or “Impact of threading dislocation on the lifetime of InAs quantum dot lasers on Si”, by Jung et al.

### DISCLOSURE OF THE INVENTION

In this context, the present invention proposes an optoelectronic component that is insensitive to dislocations, comprising a quantum-well semiconductor heterostructure able to emit a laser radiation and formed by epitaxial growth on a non-native substrate. In other words, the performances of this optoelectronic component are not affected by the dislocations due to the epitaxial growth making and are similar to those obtained by epitaxial growth on a native substrate.

Thus, the invention goes against the previously mentioned prejudice that, light sources, such as lasers, based on semiconductor materials made by epitaxial growth on non-native substrates, have degraded performances compared to the sources made by epitaxial growth on native substrates.

The invention thus proposes an optoelectronic component comprising:
a semiconductor heterostructure able to emit a laser radiation, formed of first semiconductor materials comprising a cascade of active gain areas with type-II interband radiative transition,
a support structure comprising a non-native substrate different from the first semiconductor materials, said semiconductor heterostructure being formed by epitaxial growth on the support structure, characterized in that the active areas have a dislocation density higher than 10⁷ cm², higher than 3×10⁷ cm², higher than à 5×10⁷ cm², higher than 10⁸ cm², higher than 10⁹ cm² or higher than 10¹⁰ cm².

Other non-limiting and advantageous features of the optoelectronic component according to the invention, taken individually or according to all the technically possible combinations, are the following:
the support structure further comprises, on the non-native substrate, at least one buffer layer that has a dislocation density higher than 10⁷ cm², higher than 3×10⁷ cm², higher than à 5×10⁷ cm², higher than 10⁸ cm², higher than 10⁹ cm² or higher than 10¹⁰ cm².
the support structure further comprises, on the non-native substrate, at least one buffer layer that has a thickness lower than or equal to 3 micrometres, lower than or equal to 2 micrometres or lower than or equal to 1 micrometre.
the support structure further comprises a first additional transition layer, a first confinement area and a second additional transition layer,
the non-native substrate is formed of a group-IV material,
the non-native substrate is formed of silicon,
the first semiconductor materials comprise an antimonide,
the active areas are each consisted of a hole quantum well inserted between two electron quantum wells, said hole quantum well and the two electron quantum wells forming a unit located between two barrier layers,
the active areas each comprise:
a first layer of aluminium antimonide AlSb and of thickness between 1 nm and 3.5 nm,
a second layer of indium arsenide InAs and of thickness between 1 nm and 4 nm,
a third layer of ternary material based on gallium, indium and antimony, the indium content of which varies between 0% and 50%, and of thickness between 1.5 nm and 4.5 nm,
a fourth layer of indium arsenide InAs and of thickness between 1 nm and 3.5 nm,
the active areas are each located between an electron-blocking area and a hole-blocking area,
each electron-blocking area comprises:
a layer of aluminium antimonide AlSb and of thickness between 0.3 and 3 nm,
a layer of gallium antimonide GaSb and of thickness between 1.5 to 5 nm,
a layer of aluminium antimonide AlSb and of thickness between 0.3 and 3 nm,
a layer of gallium antimonide GaSb and of thickness between 2 to 5.5 nm,
a layer of aluminium antimonide AlSb and of thickness between 1 and 3.5 nm.
each hole-blocking area comprises:
a layer of indium arsenide InAs and of thickness between 3 to 6 nm,
a layer of aluminium antimonide AlSb and of thickness between 0.6 and 3 nm,
a layer of indium arsenide InAs:Si of doping density between 5×10¹⁷ and 2×10¹⁹ cm³ and of thickness between 2 to 5 nm,
a layer of aluminium antimonide AlSb and of thickness between 0.6 and 3 nm,
a layer of indium arsenide InAs:Si of doping density between 5×10¹⁷ and 2×10¹⁹ cm³ and of thickness between 1.5 to 4 nm,
a layer of gallium antimonide AlSb and of thickness between 0.6 and 3 nm,
a layer of indium arsenide InAs:Si of doping density between 5×10 ¹⁷ and 2×10¹⁹ cm³ and of thickness between 1 to 4 nm,
a layer of gallium antimonide AlSb and of thickness between 0.6 and 3 nm,
a layer of indium arsenide InAs:Si of doping density between 5×10¹⁷ and 2×10¹⁹ cm³ and of thickness between 1 to 4 nm,
a layer of gallium antimonide AlSb and of thickness between 0.6 and 3 nm,
a layer of indium arsenide InAsn and of thickness between 1 and 4 nm,
the semiconductor heterostructure has a dislocation density between 10⁶ et 10⁹ cm².

Obviously, the different features, alternatives and embodiments of the invention can be associated with each other according to various combinations, insofar as they are not incompatible or exclusive with respect to each other.

### BRIEF DESCRIPTION OF THE DRAWINGS

The following description in relation with the appended drawings, given by way of non-limiting examples, will allow a good understanding of what the invention consists of and of how it can be implemented.

In the appended drawings:

FIG. 1 is a schematic view of an embodiment of an optoelectronic component according to the invention;

FIG. 2 is a schematic view of an embodiment of an active area according to the invention;

FIG. 3 is a schematic view of a type-II quantum well;

FIG. 4 is a schematic view of a type-II quantum well with dislocations;

FIG. 5 shows the operating principle of a cascade of active areas;

FIG. 6 is a schematic view of an embodiment of a hole-blocking area and an electron-blocking area according to the invention;

FIG. 7 shows the band diagram of the embodiment of the unit formed by an active are, a hole-blocking area and an electron-blocking area of FIG. 6.

FIG. 8 shows the evolution, as a function of the power supply current, of the power per facet of the laser radiation emitted by an optoelectronic component made according to the combination of the embodiments of FIGS. 1, 2 and 6.

FIG. 9 shows the evolution, as a function of the power supply current, of the spectrum of the laser radiation emitted by an optoelectronic component according to the combination of the embodiments of FIGS. 1, 2 and 6.

FIG. 10 shows the evolution, as a function of the temperature, of the spectrum of the laser radiation emitted by an optoelectronic component according to the combination of the embodiments of FIGS. 1, 2 and 6.

FIG. 11 shows the lifetime measurement of the optoelectronic component according to the combination of the embodiments of FIGS. 1, 2 and 6.

FIG. 12 shows the evolution of the power per facet of the laser radiation emitted by an optoelectronic component of structure similar to the combination of the embodiments of FIGS. 1, 2 and 6, but made by epitaxial growth on a native substrate.

FIG. 13 shows the evolution, as a function of the temperature, of the spectrum of the laser radiation emitted by an optoelectronic component of structure similar to the combination of the embodiments of FIGS. 1, 2 and 6, but made by epitaxial growth on a native substrate.

FIG. 14 shows the evolution, as a function of the power supply current, of the power per facet of the laser radiation emitted by an optoelectronic component similar to the embodiment of FIG. 1, but made by epitaxial growth on a native substrate.

FIG. 15 shows the evolution, as a function of the power supply current, of the power per facet of the laser radiation emitted by an optoelectronic component similar to the embodiment of FIG. 1.

FIG. 16 shows the evolution, as a function of the power supply current, of the power per facet of the laser radiation emitted by an optoelectronic component similar to the embodiment of FIG. 1, but made by epitaxial growth on a native substrate.

FIG. 17 shows the evolution, as a function of the power supply current, of the power per facet of the laser radiation emitted by an optoelectronic component similar to the embodiment of FIG. 1.

FIG. 18 is a schematic view of another embodiment of an optoelectronic component according to the invention.

### DETAILED DESCRIPTION

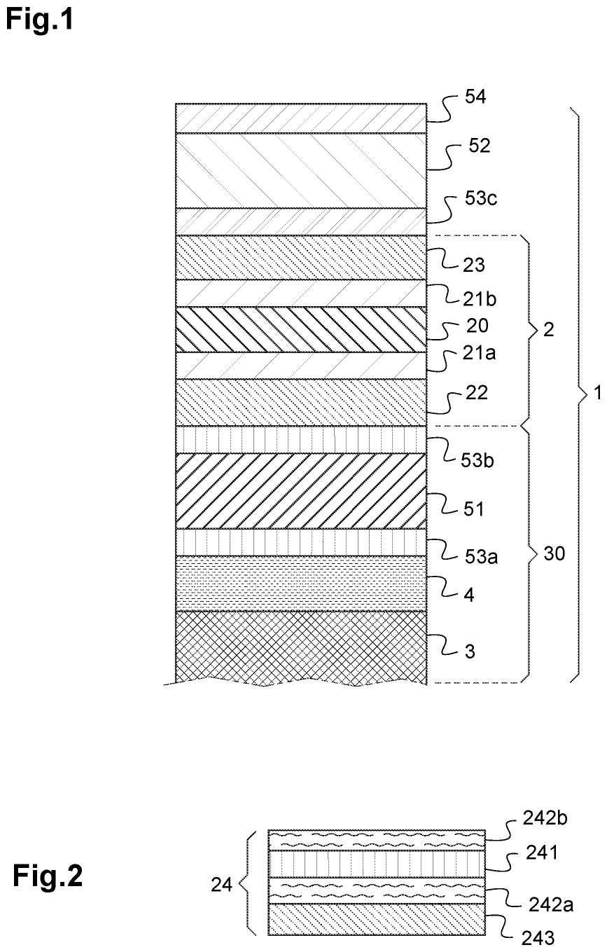

FIG. 1 schematically shows an embodiment of an optoelectronic component according to the invention, designated as a whole by reference 1.

The optoelectronic component 1 comprises a support structure 30 on which will be formed by epitaxial growth a semiconductor heterostructure 2 able to emit a laser radiation.

The support structure 30 comprises at least a non-native substrate or “wafer” 3. As used herein, “non-native substrate” means a substrate formed of a material that is different from the materials forming the semiconductor heterostructure 2. According to the example illustrated, the non-native substrate 3 is a substrate made of silicon Si (001), it being understood that the substrate could also be made of germanium, gallium arsenide, gallium phosphide, or indium phosphide.

In the present case, the support structure 30 further comprises a stack of several semiconductor layers successively deposited on one another by epitaxial growth on the non-native substrate 3. The type of epitaxy can be chosen from molecular-jet epitaxy, chemical-jet epitaxy or metal-organic vapour-phase epitaxy.

Therefore, the support structure 30 comprises successively and from the substrate 3: a buffer layer 4, a first additional transition layer 53a, a first confinement area 51 (also “cladding” layer), then a second additional transition layer 53b. The role of the buffer layer and the transition layers is to adapt the changes in the conduction band energy minimum from one layer to the next.

As an alternative, a layer could be added in the buffer layer 4 in order to make a specific lower contact layer as will described hereinafter.

Here, the buffer layer 4 is made of gallium antimonide GaSb:Te and has a thickness between 100 nm and 3 μm. According to the example illustrated, the buffer layer has a thickness of 1500 nm.

In the present case, the first confinement area 51 is formed of a significant number of repetitions of the superposition of a layer of aluminium antimonide AlSb of thickness between 1 nm and 4 nm and a layer of indium arsenide InAs:Si of thickness between 1 nm and 4 nm. According to the example illustrated, the layer of aluminium antimonide AlSb has a thickness of 2.3, whereas the layer of indium arsenide InAs:Si has a thickness of 2.4 nm and 685 repetitions thereof are made.

The first additional transition layer 53a and the second additional transition layer 53b are made of an aluminium antimonide and indium arsenide AlSb/InAs alloy each having a thickness between 1.5 nm and 3.5 nm.

The support structure 30 is made by an epitaxial growth technique chosen from the above-mentioned techniques.

The semiconductor heterostructure 2, able to emit a laser radiation, is then deposited in successive layers by epitaxial growth on the support structure 30. The semiconductor heterostructure 2 is formed of a stack of semiconductor material regions and layers.

According to the example illustrated, the semiconductor heterostructure comprises, from the last layer of the support structure 30 (i.e. the layer furthest from the substrate 3), a region 22 forming a first confinement heterostructure. In the present case, the region 22 is made of gallium antimonide GaSb:Te and has a thickness between 100 nm and 1.2 μm, and for example 400 nm.

The semiconductor heterostructure 2 comprises successively, from the region 22: a first transition layer 21a, a light-emitting region 20 that will be described in more detail hereinafter, a second transition layer 21b, a region 23 forming a second confinement heterostructure.

According to the example illustrated, the first transition layer 21a and the second transition layer 21b are made of an aluminium antimonide and indium arsenide AlSb/InAs alloy, of respective thickness between 0.3 nm and 3.5 nm. The region 23 is, as the region 22, made of gallium antimonide GaSb:Te, having a thickness of 400 nm.

Additional layers to complete the optoelectronic component 1 according to the invention are also deposited in successive layers and by epitaxial growth on the semiconductor heterostructure 2.

Therefore, on the confinement region 23 of the semiconductor heterostructure 2, is located a third additional transition layer 53c. For example, this third additional transition layer 53c is made of an aluminium antimonide and indium arsenide AlSb/InAs alloy.

On the third additional transition layer 53c are located, in the order, firstly, a second confinement area 52, and secondly, an upper contact layer 54. In the present case, the second confinement area 52 is formed, like the first confinement area 51, of a significant number of repetitions of the superposition of a layer of aluminium antimonide AlSb of thickness between 1 nm and 4 nm and a layer of indium arsenide InAs:Si of thickness between 1 nm and 4 nm. According to the example illustrated, the layer of AlSb has a thickness of 2.3 nm, whereas the layer of InAs:Si has a thickness of 2.4 nm. Moreover, the upper contact layer 54 is a layer of indium arsenide InAs:Si of thickness between 5 nm and 50 nm, for example of 20 nm.

The light-emitting region 20 of the semiconductor heterostructure 2 is formed of a cascade of active areas 24.

In a semiconductor laser source, the active area is the spatial area in which occurs

the laser radiation emission. The active area is a confinement area for charge carriers of the electron and hole type. A hole is defined as an absence of electron in a valence band of a semiconductor material. The active area can be consisted of one or several layers of semiconductor materials. The photon emission is produced after a recombination of an electron-type charge carrier with a hole-type charge carrier.

In the embodiment of FIG. 1, each active area 24 has a structure such as that shown in FIG. 2. This structure is composed of a stack of layers 243, 242a, 241 and 242b. In the present case, these layers have the following characteristics: the layer 241 is made of a ternary material based of gallium, indium and antimony Ga_{0.65}In_{0.35}Sb, and of thickness between 1.5 nm and 4.5 nm, for example 3 nm; the layers 242a and 242b are made of indium arsenide InAs and have respective thickness each between 1 nm and 4 nm, for example 1.6 nm and 1.4 nm; the layer 243 is made of aluminium antimonide AlSb, and of thickness between 1 nm and 3.5 nm, in the present case 2.5 nm. The composition of the ternary material based on gallium, indium and antimony of the layer 241 may vary from 0% of indium to 50% of indium. The structure composed of the stack of layers 243, 242a, 241 and 242b is called “W-band” structure. The layer 211 is a hole quantum well and is surrounded with layers 212a and 212b each forming an electron quantum well.

Therefore, in the embodiment of FIG. 1, each active area 24 is an active area with an interband transition based on a type-II quantum well, i.e. in which the extrema of the conduction band and the valence band of the materials making up the quantum well are spatially spaced apart.

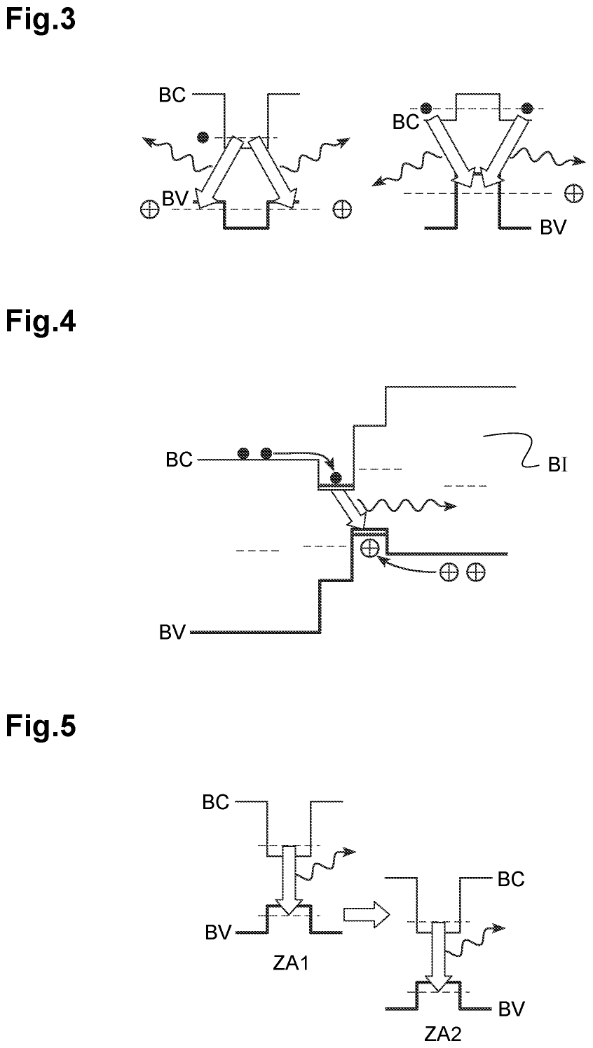

FIG. 3 schematically shows a type-II quantum well. The limit of the conduction band is materialized therein by the curve BC and the limit of the valence band is materialized by the curve BV. The dotted lines schematically represent a possible level of energy for an electron (black round) and for a hole (circle with a “plus” sign inside). The recombinations between electrons and holes are materialized by the thick vertical arrows and the photon emissions are materialized the by wavy arrows. It can be observed that the minimum of the conduction band and that of the valence band are located in a first material, and that the maximum of the conduction band and that of the valence band are located in another material. If charge carriers (electrons and holes) are injected into the type-II quantum well, they are spatially spaced apart, but they can nevertheless recombine together with a reduced probability.

As mentioned in introduction, the epitaxial growth on a substrate that has not the same mesh parameter as the epitaxed material, as this is the case for the making of the optoelectronic component 1 according to the invention, generates a very high dislocation density within the component formed, i.e. a dislocation density higher than 10⁷ cm². For example here, the optoelectronic component, and in particular the active areas 24 thereof, have a dislocation density of 5×10 ⁸ cm².

In a semiconductor material, the dislocations can be modelled by energy levels located in the forbidden energy band (“gap”), i.e. the energy band between the conduction band and the valence band.

FIG. 4 schematically shows a type-II quantum well with dislocations. The line BC marks the boundary of the conduction band BC, the line BV marks the boundary of the valence band BV and, between these two lines is located the energy gap BI. The energy levels associated with the dislocations are represented by dotted lines.

It can be observed that these energy levels are structurally spaced apart from the middle, where the radiative recombinations occur. An example of radiative recombination is represented by a solid line arrow. It can be observed that the levels of energy modelling the dislocations cannot intercept the solid line arrow. In other words, it is not possible for the charge carriers to recombine together in a radiative way via the dislocations within active areas with type-II radiative transition.

In this way, the inventors were able to demonstrate that using active areas with type-II radiative transition makes it possible to eliminate the non-radiative recombinations at the dislocations. These non-radiative recombinations, that affect the emission efficiency in the active areas, thus do not occur in the optoelectronic component 1 according to the invention.

Moreover, in the light-emitting region 20, the active areas are arranged in cascade. The principle of the cascade arrangement, illustrated in FIG. 5, enables a recycling of the carriers from an active area to the following active area. FIG. 5 schematically illustrates a first active area ZA1 juxtaposed to a second active area ZA2. The first active area ZA1 and the second active area ZA2 have the same physical structure. For example, they are each consisted of the same stack of semiconductor layers. The first active area ZA1 and the second active area ZA2 thus have the same band structure.

Under the effect of an electric field (not shown), making electrons travel from the left to the right in FIG. 5, an electron can for example recombine in a radiative way with a hole in the first active area ZA1, therefore emitting a photon. Electric field application has for effect to vertically translate the band structure of the second active area ZA2 with respect to the band structure of the first active area. The electric field is supposed to be configured to lower the band structure of the second active area ZA2, i.e. to reduce all the energy levels of the second active area ZA2. Consequently, the electron continuing its travel from the left to the right in the cascade is able to reach the conduction band of the second active area ZA2. The electron can then recombine with a hole in the second active area ZA2 and emit therein another photon.

Therefore, the cascade arrangement of the active areas makes it possible to obtain a higher gain and hence to provide more optical power.

Advantageously, each active area 24 is surrounded on one side by a hole-blocking area 22, and on the other side, by an electron-blocking area 23.

As used herein, “surrounded” means that, if electron-type charge carriers are injected into the light-emitting region 20 consisted of a cascade of active areas 24, the electron-type charge carriers travelling in the light-emitting region 20 meet a hole-blocking area 22, then an active area 24, then an electron-blocking area 23.

Reciprocally, due to the opposite direction of travel of the holes with respect to the travel direction of the electrons, the hole-type charge carriers, during their travel in the light-emitting region 20, meet an electron-blocking area 23, then an active area 21, then a hole-blocking area 22.

Each electron-blocking area 23 has for function to prevent the travel of electrons in one direction, more precisely, from the active area 24 to the electron-blocking area 23. In other words, the electrons reaching an active area 21 do not travel beyond the latter.

Each hole-blocking area 22 has for function to prevent the travel of holes in one direction, more precisely, from the active area 24 to the hole-blocking area 22. In other words, the holes do not travel beyond the active area 24.

Therefore, the electrons and the holes cannot give rise to non-radiative recombinations at the dislocations located around the active areas 24, i.e. in an electron-blocking area 23 or in a hole-blocking area 22, due to the electron and hole blocking in the active areas 24 once these latter have reached the active areas 24.

As a conclusion, in the optoelectronic component 1 according to the invention, the non-radiative recombinations are eliminated by the use of active areas with type-II interband transition and hole-and electron-blocking areas located around each active area 24.

In the embodiment of the active area 24 shown in FIG. 2, the hole-blocking area is located under the layer 243 and the electron-blocking area is located on the layer 242b.

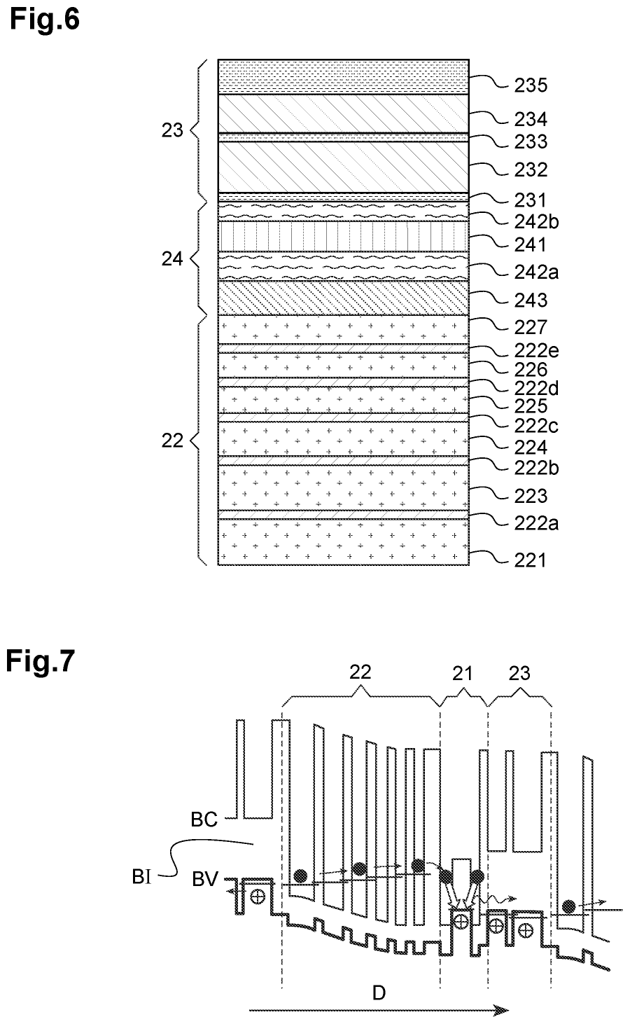

FIG. 6 illustrates an example of unit formed of an active area 24 surrounded by a hole-blocking area 22 and a hole-blocking area 23.

In FIG. 6, the hole-blocking area 22 is composed of a stack of eleven layers. More generally, the hole-blocking area 22 can be made with a stack of eight to eighteen layers. In the present case, the hole-blocking area 22 is composed as follows:
a layer 221 of indium arsenide InAs and of thickness between 3 nm and 6 nm, for example here 4.2 nm;
a layer 222a of aluminium antimonide AlSb and of thickness between 0.6 and 3 nm, here 1.2 nm;
a layer 223 of indium arsenide InAs:Si of doping density 4.5×10¹⁸ cm³, or more generally between 5×10¹⁷ and 2×10¹⁹ cm³, and of thickness between 2 nm et 5 nm, in the present case, 3.2 nm;
a layer 222b of aluminium antimonide AlSb and of thickness between 0.6 nm and 3 nm, for example here 1.2 nm;
a layer 224 of indium arsenide InAs:Si of doping density 4.5×10¹⁸ cm³, or more generally between 5×10¹⁷ and 2×10¹⁹ cm³, and of thickness between 1.5 nm and 4 nm, in the present case, 2.5 nm;
a layer 222c of aluminium antimonide AlSb and of thickness between 0.6 nm and 3 nm, here 1.2 nm;
a layer 225 of indium arsenide InAs:Si of doping density 4.5×10¹⁸ cm³, or more generally between 5×10¹⁷ and 2×10¹⁹ cm³, and of thickness between 1 nm and 4 nm, for example, 2 nm;
a layer 222d of aluminium antimonide AlSb and of thickness between 0.6 nm and 3 nm, here 1.2 nm;
a layer 226 of indium arsenide InAs:Si of doping density 4.5×10¹⁸ cm³, or more generally between 5×10¹⁷ and 2×10¹⁹ cm³, and of thickness between 1 nm and 4 nm, in the present case, 1.7 nm;
a layer 222e of aluminium antimonide AlSb and of thickness between 1 nm and 4 nm, here 1.2 nm;
and a layer 227 of indium arsenide InAs and of thickness between 1 nm and 4 nm, for example 1.5 nm.

In FIG. 6, the electron-blocking area 23 is composed of a stack of five layers. In the present case, the electron-blocking area 23 is composed as follows:
a layer 231 of aluminium antimonide AlSb and of thickness between 0.3 nm and 3 nm, for example, 1 nm;
a layer 232 of gallium antimonide GaSb and of thickness between 1.5 nm and 5 nm, here, 3.5 nm;
a layer 233 of aluminium antimonide AlSb and of thickness between 0.3 nm and 5 nm, in the present case, 1 nm;
a layer 234 of gallium antimonide material and of thickness between 2 nm and 5.5 nm, here 4.5 nm;
a layer 235 of aluminium antimonide AlSb and of thickness between 1 nm and 3.5 nm, for example 2.5 nm.

FIG. 7 illustrates the band diagram of the unit, illustrated in FIG. 6, formed of the active area 24, the hole-blocking area 22 and the electron-blocking area 23. The arrow D shows the travel direction of the electron-type charge carriers under the effect of the application of an electric field to optoelectronic component 1. In this case, the direction of travel of the hole-type charge carriers under the effect of the application of the electric field is the direction opposite to arrow D.

After passing through a hole-blocking area 22, the electron-type charge carriers reach the active area 24 and are blocked therein due to the presence of the electron-blocking area 23 adjacent to the active area 24. The electron-type charge carriers are however recycled following the radiative recombinations with the hole-type charge carriers. Indeed, after a radiative recombination, the electrons take the place of holes in the valance band, and may transit directly from the valence band towards the conduction band and travel towards the following active area 21.

The optoelectronic component comprising the combination of structures illustrated in FIGS. 1, 2 and 6, as described hereinabove, operates as follows. A voltage is applied between the upper contact layer 54 and a lower contact layer. The lower contact layer can be the substrate 3. As an alternative, the lower contact layer can be one among the layers located under the active area 2, i.e. for example, the buffer layer 4, the first additional transition layer 53a, the first confinement area 51 or the second additional transition layer 53b. Preferentially, the lower contact layer is one among the layer 4 or the layer 51. This voltage is configured to create an electric field patterning the band diagram of the light-emitting region 20 into a succession of band diagrams similar to that illustrated in FIG. 9. The electric field triggers the circulation of charge carriers through the layers included between the upper contact layer 4 and the lower contact layer.

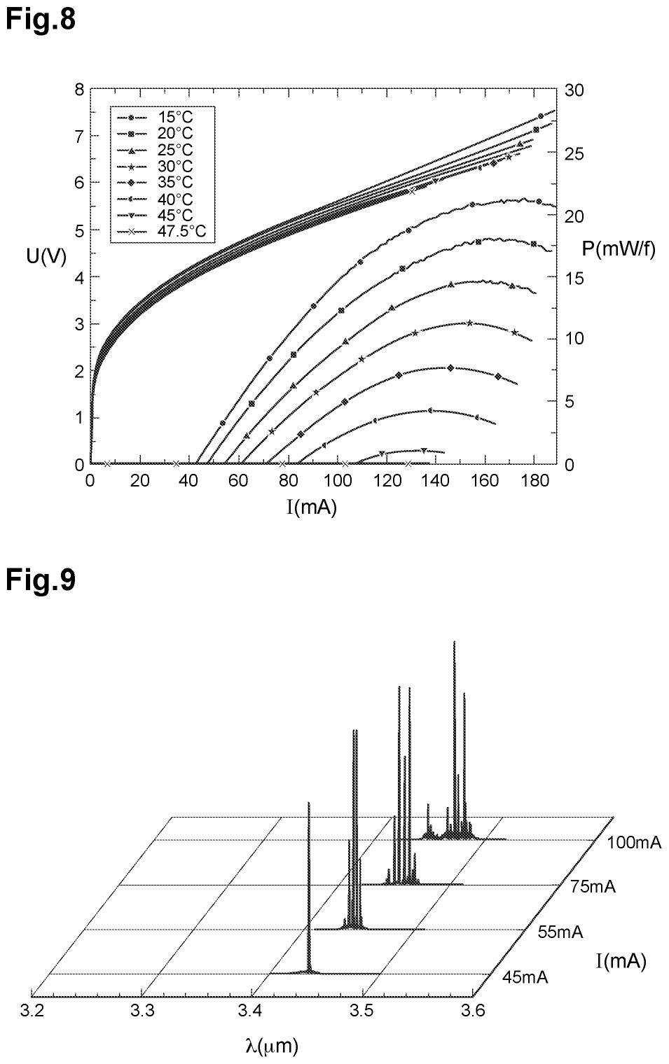

FIGS. 8, 9, 10 and 11 show the performances of the optoelectronic component 1 described hereinabove. The so-formed optoelectronic component 1 has a width of 8 micrometres and a cavity length of 2 mm, and operates up to a temperature of 45° C. in continuous power supply mode. The optoelectronic component 1 according to the above-described example has a dislocation density of 5×10⁸ cm².

FIG. 8 shows the evolution of the output power of the laser radiation emitted by the semiconductor heterostructure 2 as well as the voltage between the first confinement area 51 and the upper contact layer 54 as a function of the power supply current of the optoelectronic component 1. The different curves represent these evolutions for temperatures ranging from 15° C. to 47.5° C. It can be observed that the emission threshold at a temperature of 20° C. is of 48 mA and that a maximum power of the order of 18 mW per facet is obtained at this temperature.

FIG. 9 shows the evolution of the wavelength spectrum of the laser radiation emitted by the optoelectronic component 1 obtained at a temperature of 20° C. It can be observed that the emission wavelength is between 3.4 micrometres and 3.5 micrometres.

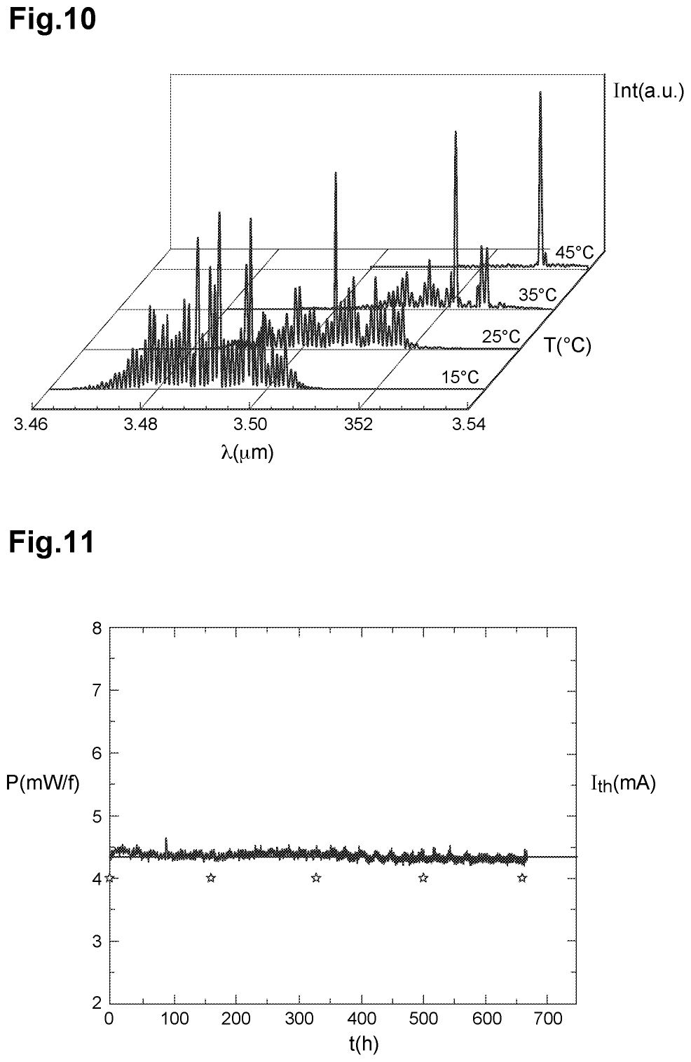

FIG. 10 shows the evolution of the wavelength spectrum of the laser radiation emitted by the optoelectronic component 1 supplied with a continuous current of 120 mA for different temperatures. It can be observed a slight translation of this spectrum towards the great wavelengths, the maximum normalized intensity value being maintained up to 45° C.

FIG. 11 shows the lifetime measurement of the optoelectronic component 1 subjected to a continuous current of 120 mA at a temperature of 40° C. It can be observed that the output power per facet (of about 4.3 mW per facet) and the threshold current (of about 77 mA) do not degrade over time.

The result illustrated in FIG. 11 can be compared with the lifetime of quantum-box laser with a dislocation density of 5×10⁸ cm², i.e. the time period after which the threshold current Iₜₕ doubles, which is of about 1,000 hours. Indeed, it can be observed that the threshold current Iₜₕ of the optoelectronic component according to the invention remains stable during a period of at least 1800 hours. Moreover, it is impossible to measure the lifetime of a quantum-well laser of the prior art.

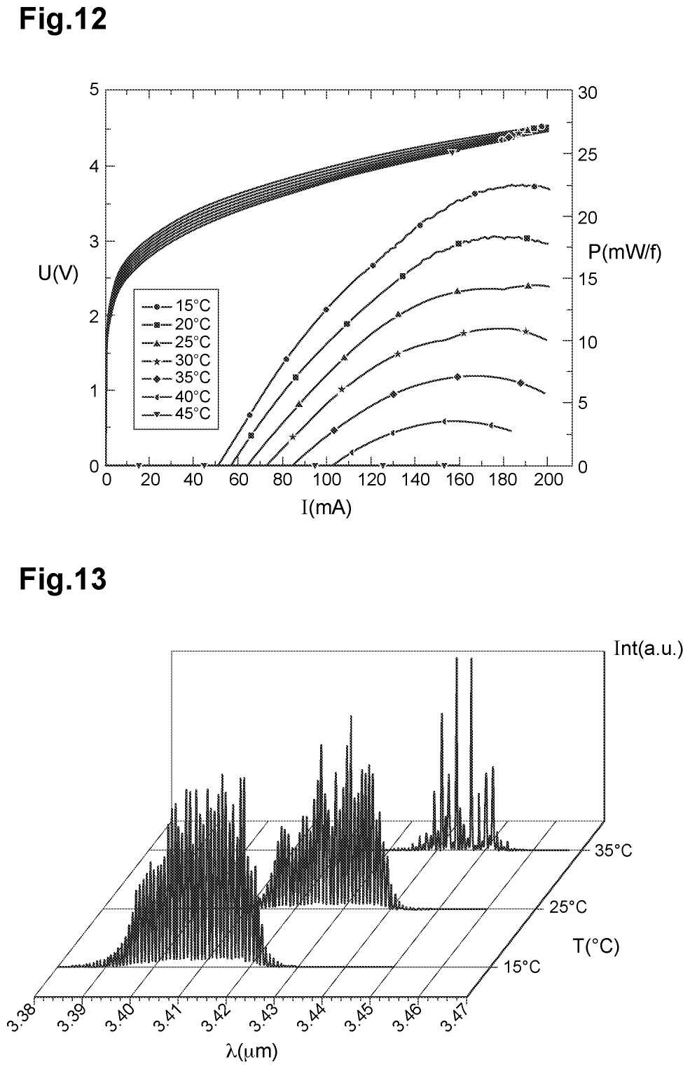

FIGS. 12 and 13 illustrate the performances of an optoelectronic component of structure almost-identical to that of the optoelectronic component 1 characterized hereinabove, but obtained by epitaxial growth on a native substrate made of gallium antimonide GaSb. This component also has a width of 8 micrometres and a cavity length of 2 mm, and operates in continuous power supply mode up to 40° C.

FIG. 12 shows the evolution of the output power of the laser radiation emitted by this component as a function of the power supply current. The different curves represent these evolutions for temperatures ranging from 15° C. to 45° C. It can be observed that the emission threshold at a temperature of 20° C. is of 52 mA and that a maximum power of the order of 18 mW per facet is obtained at this temperature.

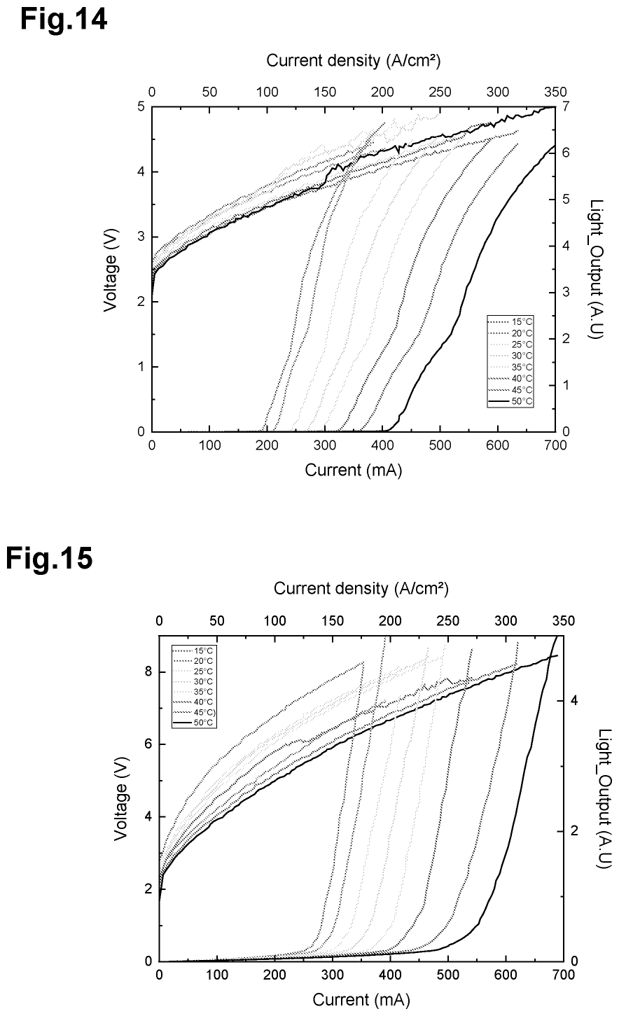

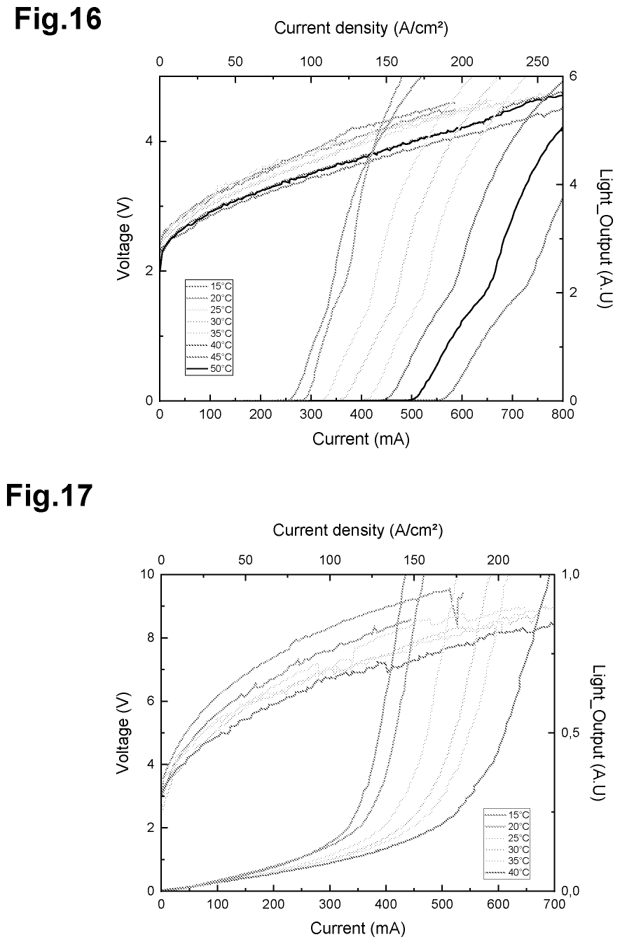

FIGS. 14 to 17 show the evolution of the laser radiation emitted by optoelectronic components according to the invention (FIGS. 15 and 17) and by optoelectronic components made on a native substrate (FIGS. 14 and 16).

Here, in the optoelectronic components made on a non-native substrate,
the buffer layer 4 is made of GaSb and has a thickness of 500 nanometres,
the first and the second confinement areas 51 and 52 are layers of AlGaAsSb that have a thickness of 2.8 micrometres,
the first and second heterostructures 22 and 23 are layers of GaSb doped with Tellurium (GaSb:Te),
the upper contact layer 54 is a layer of indium arsenide of 20 nanometres thick,
the light-emitting area 20 includes seven interband cascades.

The structure is similar in the optoelectronic components made on a native substrate, except the GaSb native substrate and the absence of buffer layer.

The results illustrated by FIGS. 14 and 15 correspond to optoelectronic components that have a cavity length of 2 millimetres. The different curves represent these evolutions for temperatures ranging from 15° C. to 47.5° C.

It can be observed that the performances relating to the threshold current density are very similar for the two components at 20° C.: 105 A/cm² for the component on a non-native substrate and 130 A.cm² for the component on a native substrate. There is thus no degradation of the performances due to the presence of dislocations in the component made on a non-native substrate.

The results illustrated by FIGS. 16 and 17 correspond to optoelectronic components that have a cavity length of 3 millimetres. The different curves represent these evolutions for temperatures ranging from 15°° C. to 47.5° C.

It can be observed that the performances relating to the threshold current density are very similar for the two components at 20° C.: 110 A.cm² for the component on a non-native substrate and 120 A.cm² for the component on a native substrate. There is thus no performance degradation due to the presence of dislocations in the component made on a non-native substrate.

It can thus be observed that, contrary to what literature teaches and surprisingly, the high dislocation density in the optoelectronic component 1 according to the invention does not degrade the performances thereof in terms of output power, maximum operating temperature, threshold current and lifetime, in comparison with an optoelectronic component having an almost-similar structure but obtained by epitaxial growth on a native substrate made of gallium antimonide GaSb.

The present invention is not in any way limited to the embodiments described hereinabove in relation with FIGS. 1 to 117, and the person skilled in the art will be able to make any possible change within the scope of the appended claims.

Therefore, the first confinement area and the second confinement area can be formed of another material than that described hereinabove and in particular a quaternary material based on aluminium, gallium, arsenic and antimony AlGaAsSb.

For example, the hole-blocking area can be a stack of layers between 6 and 16 in number, formed of pairs of layers made of pentanary/quinary materials based, respectively, on aluminium, gallium, indium, arsenic and antimony, and indium, aluminium, gallium, antimony and arsenic Al(GaInAs)Sb/In(AlGaSb)As, with a doping of the layers with In(AlGaSb)As present on all or part of these layers.

As another example, other quantum-well structures for the active areas 21 can be contemplated, being formed by alternations of hole wells and electrons wells, provided that the active areas are active gain areas with type-II interband radiative transition.

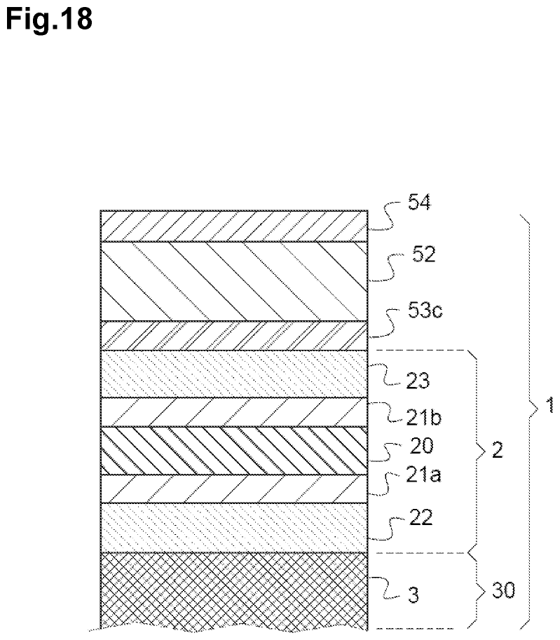

Finally, it has been demonstrated that the optoelectronic component according to the invention is insensitive to dislocations. It is therefore possible to dispense with the need for an intermediate layer between the substrate 3 and the heterostructure 22. Therefore, in certain embodiments, in particular that shown in FIG. 18, the heterostructure 2 is made directly on the substrate 3. Thus, it has no buffer layer 4 nor confinement area 21, as it was the case in the previously described embodiments. In such embodiments, the substrate 3 plays the role of confinement area and the confinement heterostructure 22 the role of buffer layer.

1. An optoelectronic component comprising:
a semiconductor heterostructure able to emit a laser radiation, formed of first semiconductor materials comprising a cascade of active gain areas with type-II interband radiative transition,
a support structure comprising a non-native substrate different from the first semiconductor materials, said semiconductor heterostructure being formed by epitaxial growth on the support structure,
wherein the active areas have a dislocation density higher than 10⁷.cm⁻².

2. The optoelectronic component according to claim 1, wherein the support structure further comprises, on the non-native substrate, at least one buffer layer that has a dislocations density higher than 10⁷.cm⁻².

3. The optoelectronic component according to claim 1, wherein the semiconductor heterostructure is made directly on the non-native substrate.

4. The optoelectronic component according to claim 2, wherein the support structure further comprises a first additional transition layer, a first confinement area and a second additional transition layer.

5. The optoelectronic component according to claim 1, wherein the non-native substrate is formed of a group-IV material.

6. The optoelectronic component according to claim 5, wherein he non-native substrate is formed of silicon.

7. The optoelectronic component according to claim 1, wherein the first semiconductor materials comprise an antimonide.

8. The optoelectronic component according to claim 1, wherein the active areas are each consisted of a hole quantum well inserted between two electron quantum wells, said hole quantum well and the two electron quantum wells forming a unit located between two barrier layers.

9. The optoelectronic component according to claim 1, wherein the active areas each comprise:
a first layer of aluminium antimonide AlSb and of thickness between 1 nm and 3.5 nm,
a second layer of indium arsenide InAs and of thickness between 1 nm and 4 nm,
a third layer of ternary material based on gallium, indium and antimony, the indium content of which varies between 0% and 50%, and of thickness between 1.5 nm and 4.5 nm,
a fourth layer of indium arsenide InAs and of thickness between 1 nm and 3.5.

10. The optoelectronic component according to claim 1, wherein the active areas are each located between an electron-blocking area and a hole-blocking area.

11. The optoelectronic component according to claim 10, wherein:
each electron-blocking area comprises:
a layer of aluminium antimonide AlSb and of thickness between 0.3 and 3 nm,
a layer of gallium antimonide GaSb and of thickness between 1.5 to 5 nm,
a layer of aluminium antimonide AlSb and of thickness between 0.3 and 3 nm,
a layer of gallium antimonide GaSb and of thickness between 2 to 5.5 nm,
a layer of aluminium antimonide AlSb and of thickness between 1 and 3.5 nm,
each hole-blocking area comprises:
a layer of indium arsenide InAs and of thickness between 3 to 6 nm,
a layer of aluminium antimonide AlSb and of thickness between 0.6 and 3 nm,
a layer of indium arsenide InAs:Si of doping density between 5×10¹⁷ and 2×10¹⁹ cm⁻³ and of thickness between 2 to 5 nm,
a layer of aluminium antimonide AlSb and of thickness between 0.6 and 3 nm,
a layer 224 of indium arsenide InAs:Si of doping density between 5×10¹⁷ and 2×10¹⁹ cm⁻³ and of thickness between 1.5 to 4 nm,
a layer of gallium antimonide GaSb and of thickness between 0.6 and 3 nm,
a layer of indium arsenide InAs:Si of doping density between 5×10¹⁷ and 2×10¹⁹ cm⁻³ and a thickness between 1 to 4 nm,
a layer of gallium antimonide GaSb and of thickness between 0.6 and 3 nm,
a layer of indium arsenide InAs:Si of doping density between 5×10¹⁷ and 2×10¹⁹ cm⁻³ and a thickness between 1 to 4 nm,
a layer of gallium antimonide AlSb and of thickness between 0.6 and 3 nm,
a layer of indium arsenide InAs and of thickness between 1 to 4 nm.

12. The optoelectronic component according to claim 1, wherein the semiconductor heterostructure has a dislocation density between 10⁶ and 10⁹ cm⁻².
